(19) United States
(12) Patent Application Publication
(10) Pub. No.: US 2025/0169086 A1
(43) Pub. Date: May 22, 2025

(54) SEMICONDUCTOR ELEMENT, SEMICONDUCTOR DEVICE, AND MANUFACTURING METHOD FOR SEMICONDUCTOR ELEMENT

(71) Applicant: KYOCERA Corporation, Kyoto-shi, Kyoto (JP)

(72) Inventor: Hayao KASAI, Redwood City, CA (US)

(73) Assignee: KYOCERA Corporation, Kyoto-shi, Kyoto (JP)

(21) Appl. No.: 18/841,511

(22) PCT Filed: Feb. 28, 2023
(86) PCT No.: PCT/JP2023/007438

§ 371 Date: Aug. 26, 2024

(30) Foreign Application Priority Data
Feb. 28, 2022 (JP) 2022-029981

(51) Int. Cl. H10D 8/60; H10D 8/01; H10D 62/10; H10D 62/85

(52) U.S. Cl. CPC H10D 8/60; H10D 8/051; H10D 62/114; H10D 62/8503

(57) ABSTRACT

A semiconductor element includes a semiconductor layer having at least one MESA structure, a field plate disposed covering at least a part of the semiconductor layer, and an insulating film located between the semiconductor layer and the field plate. The semiconductor layer is an n-type gallium nitride layer, and a thickness of a bottom portion of the insulating film covering a bottom portion of a groove portion of the semiconductor layer is greater than a thickness of a side wall portion of the insulating film covering a side wall portion of the groove portion of the semiconductor layer.

TECHNICAL FIELD

The present disclosure relates to a semiconductor element, a semiconductor device, and a manufacturing method for the semiconductor element.

### BACKGROUND OF INVENTION

Patent Document 1 discloses a technique of adopting a trench MOS barrier Schottky (TMBS) structure in order to reduce a leakage current in a GaN-based Schottky barrier diode.

### CITATION LIST

### Patent Literature

Patent Document 1: WO 2018/146791

### SUMMARY

A semiconductor element according to one aspect includes a semiconductor layer having at least one MESA structure; a field plate disposed covering at least a part of the semiconductor layer; and an insulating film located between the semiconductor layer and the field plate, in which the semiconductor layer is an n-type gallium nitride layer, and a thickness of a bottom portion of the insulating film covering a bottom portion of a groove portion of the semiconductor layer is greater than a thickness of a side wall portion of the insulating film covering a side wall portion of the groove portion of the semiconductor layer.

A semiconductor device according to one aspect includes the above semiconductor element.

A manufacturing method for a semiconductor element according to one aspect is a manufacturing method for the above semiconductor element, in which the insulating film includes a SiO₂ layer, and the SiO₂ layer is formed by vaporizing or plasma CVD.

### BRIEF DESCRIPTION OF THE DRAWINGS

FIG. 1 is a cross-sectional view of a semiconductor element according to an embodiment.

FIG. 2 is a flowchart for describing a manufacturing method for the semiconductor element according to the embodiment.

FIG. 3 is a flowchart for describing the manufacturing method for the semiconductor element according to the embodiment.

FIG. 4 is a flowchart for describing the manufacturing method for the semiconductor element according to the embodiment.

FIG. 5 is a flowchart for describing the manufacturing method for the semiconductor element according to the embodiment.

FIG. 6 is a cross-sectional view of a semiconductor element having a TMBS structure.

FIG. 7 is a plan view of the semiconductor element having a TMBS structure.

FIG. 8 is a cross-sectional view of a semiconductor element having a MESA structure.

FIG. 9 is a plan view of the semiconductor element having a MESA structure.

### DESCRIPTION OF EMBODIMENTS

An insulating film in a diode having at least one MESA structure is formed such that a film thickness at a trench bottom portion, which is a field plate electrode end, is the same as a film thickness at a trench side wall.

Since a high electric field is applied to the field plate electrode end and the trench bottom portion, the thickness of the insulating film is desirably increased. However, when a thickness of an entire insulating film is increased, the film thickness at the trench side wall is increased, so that the field plate effect of the trench side wall is reduced and a leakage current is increased.

A semiconductor element 1, a semiconductor device, and a manufacturing method for the semiconductor element according to an embodiment are described below. The semiconductor element 1 is a power semiconductor used in switching circuits of power converters such as inverters and converters.

### Embodiment

### Semiconductor Element

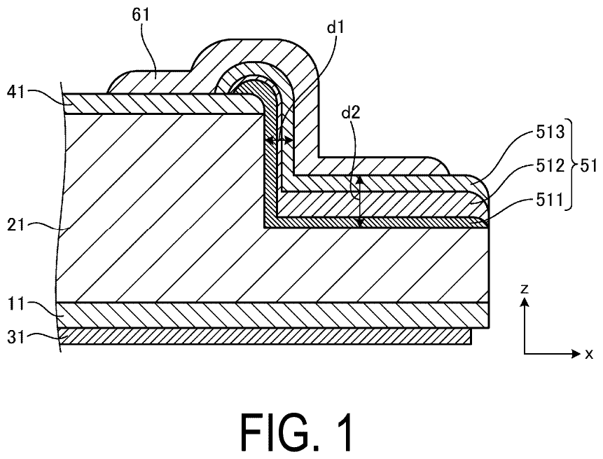

FIG. 1 is a cross-sectional view of the semiconductor element according to an embodiment. The layering direction of the semiconductor element 1 is defined as a vertical direction. The vertical direction is defined as a z-axis direction. One direction orthogonal to the layering direction is defined as a y-axis direction. A direction orthogonal to both the layering direction and the one direction is defined as an x-axis direction. The semiconductor element 1 has at least one MESA structure. In the MESA structure, in an x-axis-z-axis plane or a y-axis-z-axis plane, a front surface 21a3 connecting a front surface 21a1 and a front surface 21a2 of a semiconductor layer 21 to be described below may be perpendicular to or inclined with respect to the surface 21a2. The following description is given as an example on the assumption that the semiconductor element 1 has a TMBS structure including a plurality of MESA structures. The semiconductor element 1 includes a substrate 11, a semiconductor layer 21, a back surface electrode 31, a Schottky electrode 41, an insulating film 51, and a field plate 61.

The substrate 11 is made of gallium nitride (GaN). The thickness of the substrate 11 in the layering direction is, for example, about 300 μm or more and 400 μm or less.

The semiconductor layer 21 is an n-type GaN layer. The doping amount of n type impurities is controlled such that the semiconductor layer 21 has an electron carrier concentration less than 1e16/cm³, for example. Since the semiconductor element 1 has a TMBS structure, a groove portion (trench) is formed in at least a part of a front surface of the semiconductor layer 21. The thickness of a thick portion of the semiconductor layer 21 in the layering direction is, for example, 5 μm or more, and the thickness of a thin portion thereof is, for example, 2 μm or more.

The back surface electrode 31 is formed using, for example, Ti, Al, Ni, or Au. The thickness of Ti in the layering direction is, for example, 16 nm. The thickness of Al in the layering direction is, for example, 85 nm. The thickness of Ni in the layering direction is, for example, 25 nm. The thickness of Au in the layering direction is, for example, 50 nm.

The Schottky electrode 41 is disposed covering the thick portion of the semiconductor layer 21. The Schottky electrode 41 is located on a side opposite to the substrate 11 in the layering direction. The Schottky electrode 41 is formed using, for example, Ni. The thickness of the Schottky electrode 41 in the layering direction is, for example, 150 nm or more and 200 nm or less.

The insulating film 51 is disposed covering a groove portion 211 of the semiconductor layer 21. The insulating film 51 is disposed covering from a peripheral edge portion of the Schottky electrode 41 to the groove portion 211 of the semiconductor layer 21.

The insulating film 51 has a side wall portion and a bottom portion. The side wall portion of the insulating film 51 is a portion covering the side wall portion (trench side wall) of the groove portion 211 of the semiconductor layer 21. The bottom portion of the insulating film 51 is a portion covering the bottom portion (trench bottom portion) of the groove portion 211 of the semiconductor layer 21. A thickness d2 of the bottom portion of the insulating film 51 is greater than a thickness d1 of the side wall portion of the insulating film 51. The thickness d2 of the bottom portion of the insulating film 51 is, for example, 1.5 times or more and 5 times or less the thickness d1 of the side wall portion of the insulating film 51, and may be 2 times or more and 4 times or less the thickness d1. By making the insulating film 51 thin, the effect of electric field relaxation by the field plate is enhanced. However, since a high electric field is applied to the insulating film 51 at the bottom portion, the thickness d2 of the bottom portion of the insulating film 51 is set to 1.5 times or more and 5 times or less the thickness d1 of the side wall portion of the insulating film 51, so that the effect of helping prevent dielectric breakdown of the insulating film at the bottom portion can be further enhanced while maintaining the effect of electric field relaxation by the field plate.

The thickness d1 of the side wall portion of the insulating film 51 is not particularly limited as long as the thickness d1 is smaller than the thickness d2 of the bottom portion of the insulating film 51, but is usually 200 nm or more and 1000 nm or less, and may be 500 nm or more and 700 nm or less.

The thickness d2 of the bottom portion of the insulating film 51 is usually 200 nm or more and 1000 nm or less, and may be 500 nm or more and 700 nm or less.

When the thickness d1 of the side wall portion of the insulating film 51 and the thickness d2 of the bottom portion of the insulating film 51 do not particularly need to be distinguished from each other, the thicknesses are referred to as the thickness of the insulating film 51.

The insulating film 51 includes an Al₂O₃ layer 511 formed by an atomic layer deposition (ALD) method, a SiO₂ layer 512 (may be referred to as a first SiO₂ layer) formed by vaporizing, and a SiO₂ layer 513 (may be referred to as a second SiO₂ layer) formed by plasma chemical vapor deposition (CVD) in order from the semiconductor layer 21. The presence of the first SiO₂ layer and the second SiO₂ layer is useful in terms of having a density difference.

In the present embodiment, the Al₂O₃ layer 511 is formed on the groove portion 211 of the semiconductor layer 21 and a peripheral portion thereof. The Al₂O₃ layer 511 is also formed on the Schottky electrode 41. The Al₂O₃ layer 511 is formed by a thermal method ALD and thus has high adhesion and high coverage. Since the thermal method ALD uses no plasma, no plasma damage occurs at the time of film formation. The Al₂O₃ layer 511 has a higher dielectric constant than the SiO₂ layer 512 and the SiO₂ layer 513. The thickness of a bottom portion and a side wall of the Al₂O₃ layer 511 is, for example, 1 nm or more and 200 nm or less, and may be 10 nm or more and 100 nm or less.

In the present embodiment, the SiO₂ layer 512 is formed on the Al₂O₃ layer 511. The SiO₂ layer 512 is formed at a low temperature and is less damaged. Since the SiO₂ layer 512 is also formed on the Schottky electrode 41, plasma damage to the Schottky electrode 41 is reduced when plasma CVD is subsequently performed. The SiO₂ layer 512 has a density of 1.9 g/cm³ or more and 2.1 g/cm³ or less. The thickness of a bottom portion of the SiO₂ layer 512 is, for example, 300 nm or more and 1000 nm or less, and may be 400 nm or more and 1000 nm or less. The thickness of a side wall portion of the SiO₂ layer 512 is smaller than the thickness of the bottom portion of the SiO₂ layer 512.

In the present embodiment, the SiO₂ layer 513 is formed on the SiO₂ layer 512. Since the SiO₂ layer 513 is formed with a high insulating film density, the SiO₂ layer 513 has a high resistance to dielectric breakdown. The SiO₂ layer 513 has a density greater than 2.1 g/cm³ and equal to or less than 2.3 g/cm³. The thickness of a bottom portion and a side wall of the SiO₂ layer 513 is, for example, 100 nm or more and 500 nm or less, and may be 200 nm or more and 500 nm or less.

The field plate 61 is disposed covering the insulating film 51. The field plate 61 is disposed covering the Schottky electrode 41. A part of the Schottky electrode 41 is exposed from the field plate 61. A part of the insulating film 51 is exposed from the field plate 61.

In the semiconductor element according to the present embodiment, a negative voltage may be applied to an anode of the semiconductor element up to −500 V, and a leakage current at that time may be 1.0×10⁻¹ A/cm² or less, 1.0×10⁻² A/cm² or less, or 1.0×10³ A/cm² or less.

In the semiconductor element according to the present embodiment, a negative voltage may be applied to the anode of the semiconductor element until breakdown occurs, and a voltage at the time of breakdown may be 500 V or more, 550 V or more, or 600 V or more. On the other hand, an upper limit is not limited, but may be 1500 V or less, or may be 1000 V or less.

### Manufacturing Method

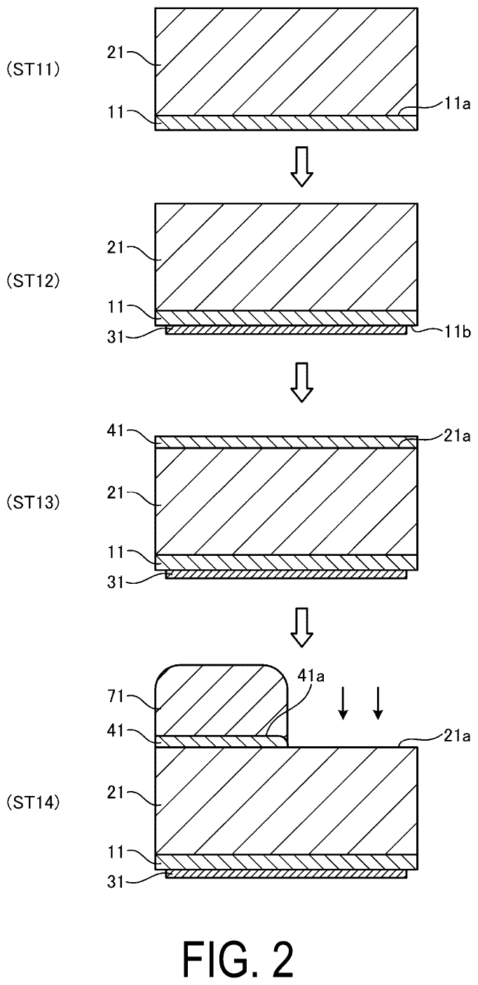

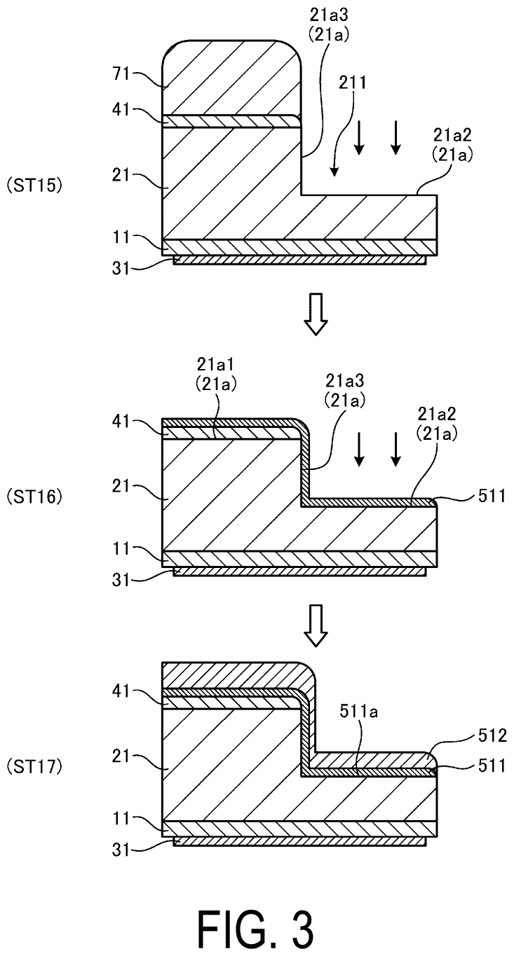

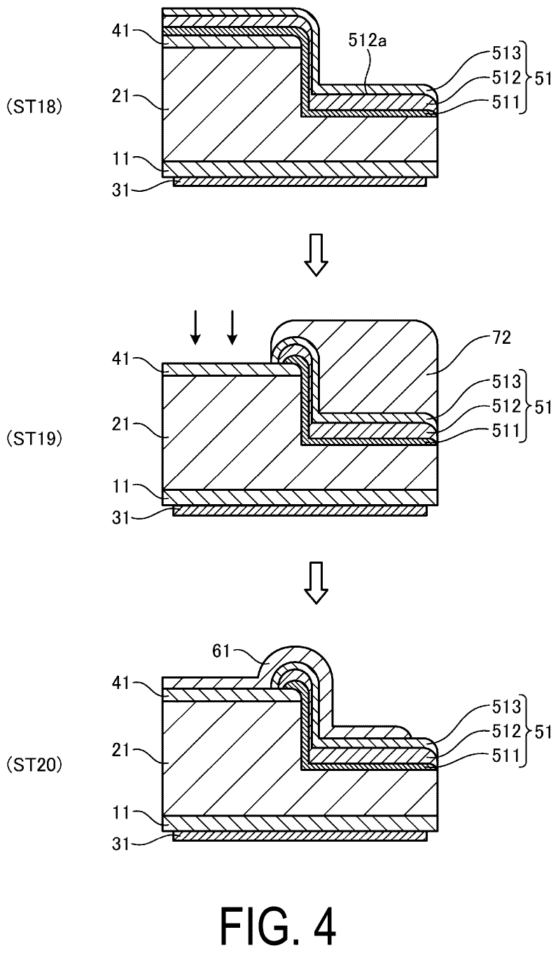

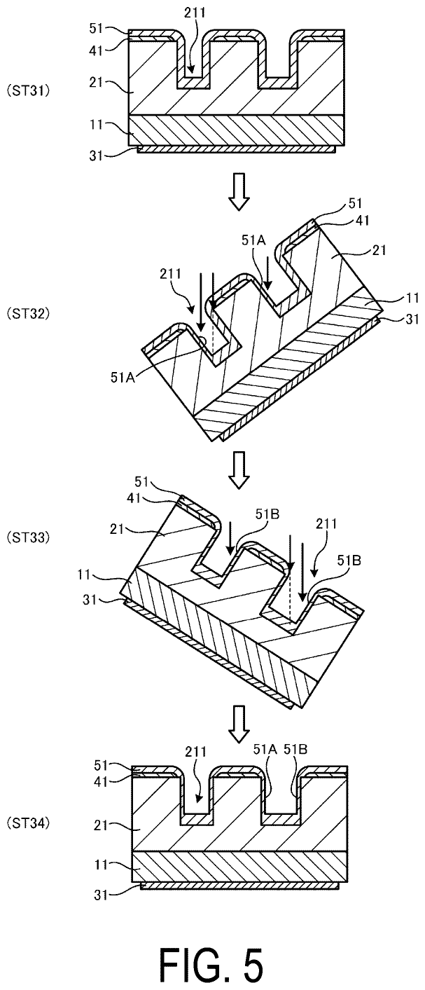

The manufacturing method for the semiconductor element 1 is described with reference to FIGS. 2 to 5. FIG. 2 is a flowchart for describing the manufacturing method for the semiconductor element according to the embodiment. FIG. 3 is a flowchart for describing the manufacturing method for the semiconductor element according to the embodiment. FIG. 4 is a flowchart for describing the manufacturing method for the semiconductor element according to the embodiment. FIG. 5 is a flowchart for describing the manufacturing method for the semiconductor element according to the embodiment. The manufacturing method for the semiconductor element 1 is performed in accordance with steps illustrated in FIGS. 2 to 5.

First, as illustrated in FIG. 2, GaN is epitaxially grown from a front surface 11a of the substrate 11 (step ST11). More specifically, the semiconductor layer 21 being an n-type semiconductor layer is epitaxially grown from the front surface 11a of the substrate 11.

The back surface electrode 31 is formed on a back surface 11b of the substrate 11 opposite to the front surface 11a (step ST12). More specifically, the back surface electrode 31 is formed on the back surface 11b of the substrate 11 by, for example, vaporizing.

The Schottky electrode 41 being a metal layer (barrier metal) is formed on the entire surface of a front surface 21a of the semiconductor layer 21 (step ST13). More specifically, the Schottky electrode 41 is formed on the entire surface of the front surface 21a of the semiconductor layer 21 by, for example, vaporizing or sputtering.

A part of the Schottky electrode 41 is wet-etched (step ST14). More specifically, a photoresist 71 is provided except for a portion of the Schottky electrode 41 to be removed, and wet etching is performed. More specifically, the remaining portion of a front surface 41a of the Schottky electrode 41 is covered with the photoresist 71. When the volume ratio of H₂SO₄ and HNO₃ is 1, the wet etching is performed under the condition that the ratio of H₂O is 10 or more and 15 or less.

Subsequently, as illustrated in FIG. 3, a part of the Schottky electrode 41 is dry-etched (step ST15). More specifically, a portion provided with no photoresist 71 in the Schottky electrode 41 is dry-etched. The photoresist 71 is removed.

In step ST14 and step ST15, the groove portion 211 of the semiconductor layer 21 is formed. The front surface 21a of the semiconductor layer 21 has the front surface 21ₐ1, the front surface 21ₐ2, and the front surface 21ₐ3. The front surface 21ₐ1 is a front surface at the time of forming the semiconductor layer 21. The front surface 21ₐ2 and the front surface 21ₐ3 are front surfaces of the groove portion 215.

The Al₂O₃ layer 511 is formed by an atomic layer deposition method (step ST16). More specifically, the Al₂O₃ layer 511 is formed covering the front surface 21ₐ2 and the front surface 21ₐ3 of the groove portion 211 of the semiconductor layer 21 and the front surface 41a of the Schottky electrode 41.

The SiO₂ layer 512 is formed by vaporizing (step ST17). More specifically, the SiO₂ layer 512 is formed covering a front surface 511a of the Al₂O₃ layer 511.

As illustrated in FIG. 4, the SiO₂ layer 513 is formed by plasma CVD (step ST18). More specifically, the SiO₂ layer 513 is formed covering a front surface 512a of the SiO₂ layer 512.

In step ST16 and step ST18, the insulating film 51 is formed.

A contact hole is formed (step ST19). More specifically, a photoresist 72 is provided covering a portion of the insulating film 51 that is not removed. The contact hole is formed by removing the insulating film 51 by wet etching or dry etching. The insulating film 51 is removed except for the groove portion 211 of the semiconductor layer 21 and a peripheral edge portion of the groove portion 211. A peripheral edge portion of the insulating film 51 is located at the peripheral edge portion of the Schottky electrode 41.

The field plate 61 is deposited (step ST20). More specifically, the field plate 61 is formed by, for example, vaporizing or sputtering so as to cover the Schottky electrode 41 and the insulating film 51.

A method for adjusting the thickness of the insulating film 51 is described with reference to FIG. 5. A process illustrated in FIG. 5 is performed after the SiO₂ layer 512 is formed in step ST17. The process illustrated in FIG. 5 may be performed after the SiO₂ layer 513 is formed in step ST18.

The back surface electrode 31, the substrate 11, the semiconductor layer 21, the Schottky electrode 41, and the insulating film 51, which have been layered, are inclined (step ST31). One side wall portion 51A of the insulating film 51 is inclined upward.

The thickness of the one side wall portion 51A of the insulating film 51 is reduced by dry etching (step ST32).

The thickness of a side wall portion 51B opposite to the one side wall portion 51A of the insulating film 51 is reduced by dry etching (step ST33). First, the back surface electrode 31, the substrate 11, the semiconductor layer 21, the Schottky electrode 41, and the insulating film 51, which have been layered, are inclined to the side opposite to the side when step ST32 is performed. The other side wall portion 51B of the insulating film 51 is inclined upward. Subsequently, dry etching is performed.

The inclination of the back surface electrode 31, the substrate 11, the semiconductor layer 21, the Schottky electrode 41, and the insulating film 51, which have been layered, is returned to horizontal (step ST34). In this way, the thickness d1 of the side wall portion 51A and the side wall portion 51B of the insulating film 51 is reduced.

Although the method in which the semiconductor layer side having the insulating film 51 is inclined is described, no particular limitation exists as long as the side wall side is locally irradiated with a reactive gas, ions, or radicals used for dry etching, and dry etching may be performed with an irradiation port for a reactive gas or the like inclined.

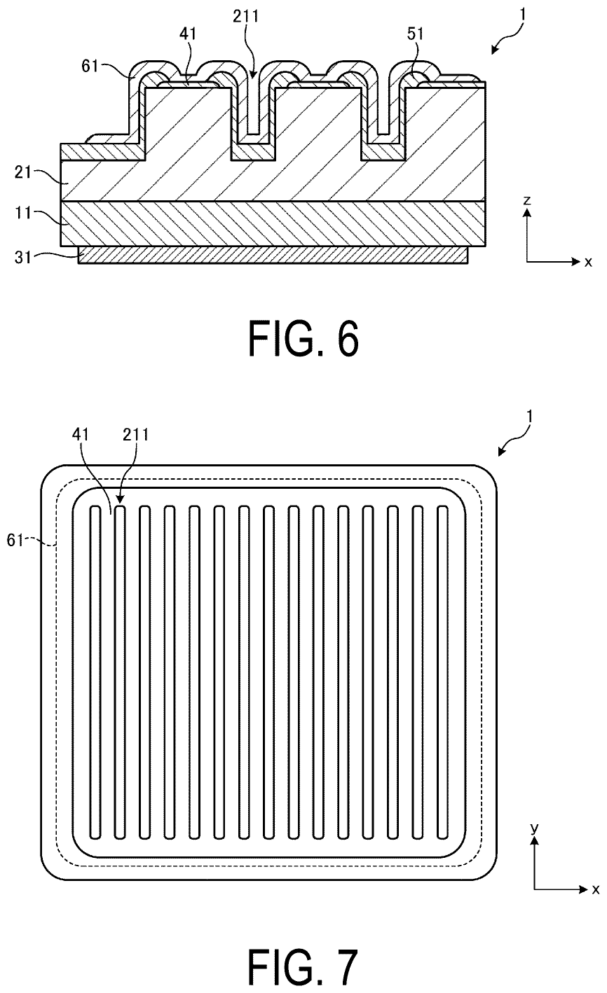

In the above-described manner, the semiconductor element 1 is manufactured. FIGS. 6 and 7 illustrate the semiconductor element 1 having a TMBS structure. FIG. 6 is a cross-sectional view of the semiconductor element having a TMBS structure. FIG. 7 is a plan view of the semiconductor element having a TMBS structure.

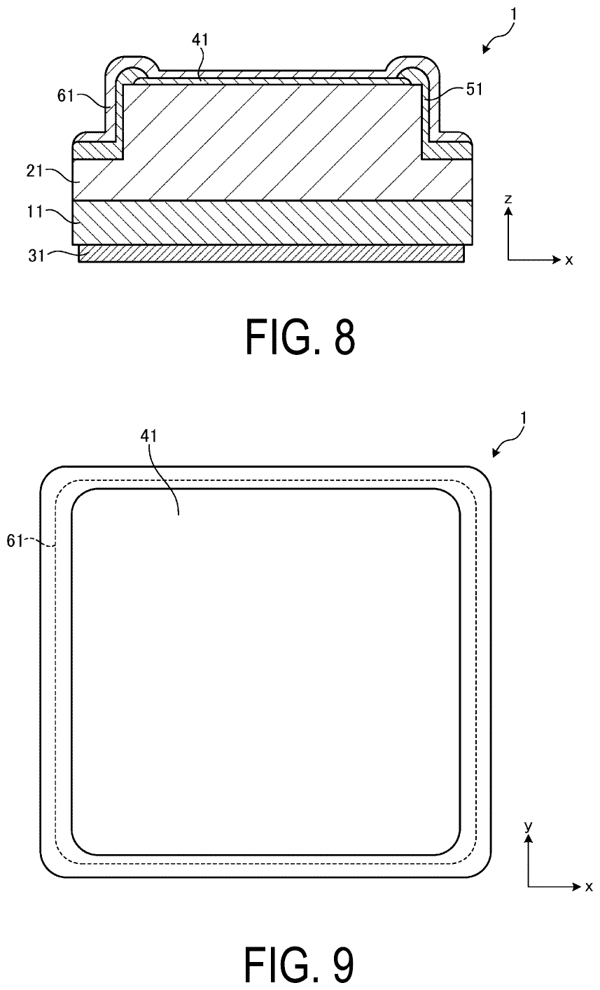

FIGS. 8 and 9 illustrate the semiconductor element 1 having one MESA structure. FIG. 8 is a cross-sectional view of the semiconductor element having a MESA structure. FIG. 9 is a plan view of the semiconductor element having a MESA structure.

### EXAMPLES

### Measurement Method

### Withstand High Voltage Load Test and Leakage Current Measurement

A negative voltage was applied to the anode of the semiconductor element until breakdown occurred, and the voltage at the time of breakdown was measured. The negative voltage was applied up to −500 V, and a leakage current at that time was measured.

### Example 1

On the basis of the above-described manufacturing method, the semiconductor element including a semiconductor layer (n-type GaN layer) having a TMBS structure was manufactured. The insulating film 51 has three layers of the Al₂O₃ layer 511, the SiO₂ layer 512, and the SiO₂ layer 513 manufactured by an atomic deposition method, a vaporizing method, and a plasma CVD method, respectively. The thicknesses of side wall portions of the respective layers were 100 nm, 100 nm, and 150 nm, and the thicknesses of bottom portions of the respective layers were 100 nm, 400 nm, and 200 nm. The ratio of the thickness d2 of the bottom portion of the insulating film 51 to the thickness d1 of the side wall portion of the insulating film 51 was 2.0.

When the obtained semiconductor element was subjected to the above-described withstand high voltage load test and leakage current measurement, the breakdown voltage was 600 V and the leakage current under −500 V load was 2.5×10⁻⁴ A/cm².

As described above, in the present embodiment, the thickness d2 of the bottom portion of the insulating film 51 is greater than the thickness d1 of the side wall portion thereof. In other words, the thickness d1 of the side wall portion of the insulating film 51 is smaller than the thickness d2 of the bottom portion thereof. Thus, according to the present embodiment, the field plate effect of the trench side wall can be improved while the withstand voltage of the insulating film at the trench bottom portion is maintained. In this way, according to the present embodiment, the leakage current can be reduced.

In the present embodiment, since the SiO₂ layer 512 is also formed on the Schottky electrode 41, plasma damage to the Schottky electrode 41 can be reduced when plasma CVD is subsequently performed.

The embodiments disclosed by the present application can be modified without departing from the main point or the scope of the invention. The embodiments and variations thereof disclosed in the present application can be combined as appropriate.

Characteristic embodiments have been described in order to fully and clearly disclose the technique according to the appended claims. However, the appended claims are not to be limited to the embodiments described above and are to be configured to embody all variations and alternative configurations that those skilled in the art may make within the underlying matter set forth in this specification.

The formation of the back surface electrode 31 in step ST12 may be performed after the Schottky electrode 41 is formed. When a step of increasing a temperature is included, for example, by performing step ST12 last, the influence on the back surface electrode 31 can be avoided.

### Variations

In the above description, the insulating film 51 is described as being formed of three layers of the Al₂O₃ layer 511, the SiO₂ layer 512, and the SiO₂ layer 513; however, no such limitation is intended. The insulating film 51 may be formed of two layers of the Al₂O₃ layer 511 and the SiO₂ layer 512 in order from the semiconductor layer 21. In this case, the thickness of the side wall portion of the SiO₂ layer 512 is smaller than the thickness of the bottom portion of the SiO₂ layer 512. The Al₂O₃ layer 511 has the same thickness at the bottom portion and the side wall portion.

The insulating film 51 may be formed of two layers of the Al₂O₃ layer 511 and the SiO₂ layer 513 in order from the semiconductor layer 21. In this case, the thickness of the side wall portion of the SiO₂ layer 513 is smaller than the thickness of the bottom portion of the SiO₂ layer 513. The Al₂O₃ layer 511 has the same thickness at the bottom portion and the side wall portion.

The insulating film 51 may be formed of two layers of the SiO₂ layer 512 and the SiO₂ layer 513 in order from the semiconductor layer 21. In this case, the thickness of the side wall portion of the SiO₂ layer 512 is smaller than the thickness of the bottom portion of the SiO₂ layer 512. The SiO₂ layer 513 has the same thickness at the bottom portion and the side wall portion.

The insulating film 51 may be formed of one layer of the SiO₂ layer 513. In this case, the thickness of the side wall portion of the SiO₂ layer 513 is smaller than the thickness of the bottom portion of the SiO₂ layer 513.

The insulating film 51 may be formed of one layer of the SiO₂ layer 512. In this case, the thickness of the side wall portion of the SiO₂ layer 512 is smaller than the thickness of the bottom portion of the SiO₂ layer 512.

The following concepts can be extracted from the present disclosure.
(1)

A semiconductor element including:
a semiconductor layer having at least one MESA structure;
a field plate disposed covering at least a part of the semiconductor layer; and
an insulating film located between the semiconductor layer and the field plate,
in which the semiconductor layer is an n-type gallium nitride layer, and
a thickness of a bottom portion of the insulating film covering a bottom portion of a groove portion of the semiconductor layer is greater than a thickness of a side wall portion of the insulating film covering a side wall portion of the groove portion of the semiconductor layer.
(2)

The semiconductor element according to (1), in which the insulating film includes a SiO₂ layer.
(3)

The semiconductor element according to (2), in which the insulating film further includes an Al₂O₃ layer.
(4)

The semiconductor element according to (2) or (3), in which the SiO₂ layer includes a first SiO₂layer having a density of 1.9 g/cm³ or more and 2.1 g/cm³ or less and a second SiO₂ layer having a density of more than 2.1 g/cm³ and 2.3 g/cm³ or less.
(5)

The semiconductor element according to any one of (1) to (4), in which the thickness of the bottom portion of the insulating film is 1.5 times or more and 5 times or less the thickness of the side wall portion of the insulating film.
(6)

A semiconductor device including the semiconductor element according to any one of (1) to (5).
(7)

A manufacturing method for the semiconductor element according to any one of (1) to (5), in which the insulating film includes a SiO₂ layer, and the SiO₂ layer is formed by vaporizing or plasma CVD.
(8)

The manufacturing method for the semiconductor element, according to (7), in which the insulating film includes a first SiO₂ layer and a second SiO₂, and the first SiO₂ layer is formed by vaporizing, and the first SiO₂ layer is formed by plasma CVD.
(9)

The manufacturing method for the semiconductor element, according to (8), in which the insulating film includes the first SiO₂ layer and the second SiO₂ in order from the semiconductor layer.
(10)

The manufacturing method for the semiconductor element, according to any one of (7) to (9), in which the insulating film further includes an Al₂O₃ layer, and the Al₂O₃ layer is formed by an atomic layer deposition method.
(11)

The manufacturing method for the semiconductor element, according to (9), in which the insulating film includes the Al₂O₃ layer and the SiO₂ layer in order from the semiconductor layer.
(12)

The manufacturing method for the semiconductor element, according to any one of (7) to (11), further including, after the insulating film is formed, locally dry-etching the side wall portion of the insulating film.

### REFERENCE SIGNS

1 Semiconductor element
11 Substrate
11a Front surface
21 Semiconductor layer
31 Back surface electrode
41 Schottky electrode
51 Insulating film
61 Field plate

1. A semiconductor element comprising:
A semiconductor element comprising:
a semiconductor layer comprising at least one MESA structure;
a field plate disposed covering at least a part of the semiconductor layer; and
an insulating film located between the semiconductor layer and the field plate,
wherein the semiconductor layer is an n-type gallium nitride layer, and
a thickness of a bottom portion of the insulating film covering a bottom portion of a groove portion of the semiconductor layer is greater than a thickness of a side wall portion of the insulating film covering a side wall portion of the groove portion of the semiconductor layer, and
the SiO₂ layer comprises a first SiO₂ layer having a density of 1.9 g/cm³ or more and 2.1 g/cm³ or less and a second SiO₂ layer having a density of more than 2.1 g/cm³ and 2.3 g/cm³ or less.

2. The semiconductor element according to claim 1, wherein the insulating film comprises a SiO₂ layer.

3. The semiconductor element according to claim 2, wherein the insulating film further comprises an Al₂O₃ layer.

4. (canceled)

5. The semiconductor element according to claim 1, wherein the thickness of the bottom portion of the insulating film is 1.5 times or more and 5 times or less the thickness of the side wall portion of the insulating film.

6. A semiconductor device comprising:
the semiconductor element according to claim 1.

7. A manufacturing method for the semiconductor element according to claim 1,
wherein the insulating film comprises a SiO₂ layer,
the SiO₂ layer is formed by vaporizing or plasma CVD, and
the SiO₂ layer comprises a first SiO₂ layer having a density of 1.9 g/cm³ or more and 2.1 g/cm³ or less and a second SiO₂ layer having a density of more than 2.1 g/cm³ and 2.3 g/cm³ or less.

8. The manufacturing method for the semiconductor element, according to claim 7,
wherein the insulating film comprises a first SiO₂ layer and a second SiO₂ layer, and
the first SiO₂ layer is formed by vaporizing, and the second SiO₂ layer is formed by plasma CVD.

9. The manufacturing method for the semiconductor element, according to claim 8, wherein the insulating film comprises the first SiO₂ layer and the second SiO₂ layer in order from the semiconductor layer.

10. The manufacturing method for the semiconductor element, according to claim 7,
wherein the insulating film further comprises an Al₂O₃ layer, and
the Al₂O₃ layer is formed by an atomic layer deposition method.

11. The manufacturing method for the semiconductor element, according to claim 10, wherein the insulating film comprises the Al₂O₃ layer and the SiO₂ layer in order from the semiconductor layer.

12. The manufacturing method for the semiconductor element, according to claim 7, further comprising, after the insulating film is formed, locally dry-etching the side wall portion of the insulating film.
